(19) United States
(12) Patent Application Publication
(10) Pub. No.: US 2012/0098037 A1
(43) Pub. Date: Apr. 26, 2012

(54) DEVICE HAVING SERIES-CONNECTED HIGH ELECTRON MOBILITY TRANSISTORS AND MANUFACTURING METHOD THEREOF

(75) Inventors: EDWARD YI CHANG, HSINCHU COUNTY (TW); HENG-TUNG HSU, TAOYUAN COUNTY (TW)

(73) Assignee: NATIONAL CHIAO TUNG UNIVERSITY, HSINCHU CITY (TW)

(21) Appl. No.: 12/955,141

(22) Filed: Nov. 29, 2010

(30) Foreign Application Priority Data
Oct. 22, 2010 (TW) 99136116

(51) Int. Cl. H01L 29/778; H01L 21/335

(52) U.S. Cl. 257/194; 438/172; 257/E29.246; 257/E21.403

(57) ABSTRACT

A manufacturing method of a device having series-connected HEMTs is presented. Transistors are formed on a substrate and integratedly serial-connected as an integrated device by interconnection wires. Therefore, the voltage of the device is the sum of the voltages across each transistors so that the device can have high breakdown voltage.

### BACKGROUND OF THE INVENTION

1. Field of the Invention The present invention is a transistor device; especially, the present invention relates to a device having series-connected high electron mobility transistors and the manufacturing method thereof.

2. Description of Related Art

GaN and GaN-based materials can be applied in micro-electronic devices of high temperature, high power, high frequency due to the properties of wide bandgap, low hot-carrier generation rate, high breakdown electrical field, high electron mobility and high electron velocity. Thus, transistors made by GaN and GaN-based materials can be used in high temperature, high speed or high power applications.

The devices of Group III-nitride (i.e., GaN) are developed to high power, high frequency, such as the transmitter of the wireless base station. The devices of Group III-nitride can be classified into various structures, such as HFET, HEMT, MODFET, and so on, and the structures are developed to increase the electron mobility of the devices. The above-mentioned devices can be used in 100 V or higher voltage and operate in high frequency, such as from 2 to 100 GHz. In semiconductor theorem, the devices is functioned by 2DEG (two dimensional electron gas) induced by piezoelectricity polarization. The 2DEG can be used for transmitting high current in low impedance loss.

However, the high temperature and the pressure applications are more and more developed, the reliability of the device used in high temperature and the pressure environment is discussed. One traditional method is forming field plate in gate in order to increase the operating voltage of the transistor, but the process of forming the field plate is complex. Furthermore, the breakdown voltage of the device is limited by the field plate and cannot be efficiently adjusted.

Another traditional method is implanting protons in the channel of the device to increase the breakdown voltage of transistor. However, the method may result in the lattice defects of the devices and change the distribution of 2DEG. Accordingly, the device characteristics may be influenced.

### SUMMARY OF THE INVENTION

One object of the present invention provides a high breakdown voltage device.

Another object of the present invention provides a low cost process to series connect the transistors into an integral device. Therefore, the manufacturing processes are not complex and the device characteristics are prevented from influence.

The present invention discloses a manufacturing method of a device having series-connected high electron mobility transistors, which comprises following steps: providing a substrate; forming a buffer layer on the substrate; forming a barrier layer on the buffer layer, wherein a two-dimensional electron gas (2DEG) is formed substantially at the hetero-interface between the barrier layer and the buffer layer to define an active area; forming at least one isolation structure, separating the buffer layer, the barrier layer and the active area so as to form at least two high electron mobility transistors (HEMTs) on the substrate; forming a source electrode and a drain electrode on the barrier layer of each of the high electron mobility transistors, wherein the source electrode and the drain electrode are electrically connected to the active area; forming a gate electrode on the barrier layer of each of the high electron mobility transistors, wherein the gate electrode is located between the source electrode and the drain electrode, and the gate electrode is electrically connected to the active area; connecting the at least two high electron mobility transistors in a series manner, wherein the source electrode of one of the at least two high electron mobility transistors is connected electrically to the drain electrode of the other one of the at least two high electron mobility transistors, and the gate electrodes of the at least two high electron mobility transistors are connected with each other.

The present invention further discloses a device having series-connected high electron mobility transistors. The device comprises at least two high electron mobility transistors (HEMTs) connected in a series manner, and the at least two high electron mobility transistors are formed on a substrate and separated by at least one isolation structure. Each high electron mobility transistor includes: a buffer layer formed on the substrate; a barrier layer formed on the buffer layer, wherein a two-dimensional electron gas (2DEG) is formed substantially' at the hetero-interface between the barrier layer and the buffer layer to define an active area; a source electrode, a drain electrode and a gate electrode, the source electrode, the drain electrode and the gate electrode being formed on the barrier layer and connected electrically to the active area. The source electrode of one of the at least two high electron mobility transistors is connected electrically to the drain electrode of the other one of the at least two high electron mobility transistors, and the gate electrodes of the at least two high electron mobility transistors are connected with each other.

The separated transistors are series connected in the manufacturing process to form an integral device. The manufacturing processes are optimized and flexible. The number of the transistors can be adjusted to meet the requirement of high voltage; therefore, the device can be used in high temperature and high pressure with high reliability.

In order to further appreciate the characteristics and technical contents of the present invention, references are hereunder made to the detailed descriptions and appended drawings in connection with the present invention. However, the appended drawings are merely shown for exemplary purposes, rather than being used to restrict the scope of the present invention.

### BRIEF DESCRIPTION OF THE DRAWINGS

FIGS. 1A to 1H shows the flow char of the manufacturing method according to the present invention;

FIG. 2 is a top-view diagram of the device according to the present invention.

### DETAILED DESCRIPTION OF THE PREFERRED EMBODIMENTS

The present invention provides a device having series-connected high electron mobility transistors (HEMTs) and a manufacturing method thereof. The manufacturing method is applied to integrate several HEMTs (e.g., at least two HEMTs) into a unity and integrated device which has series-connected high electron mobility transistors. Thus, the breakdown voltage of the device is increased so that the device can be used in high power electrical systems or in high temperature, high voltage applications.

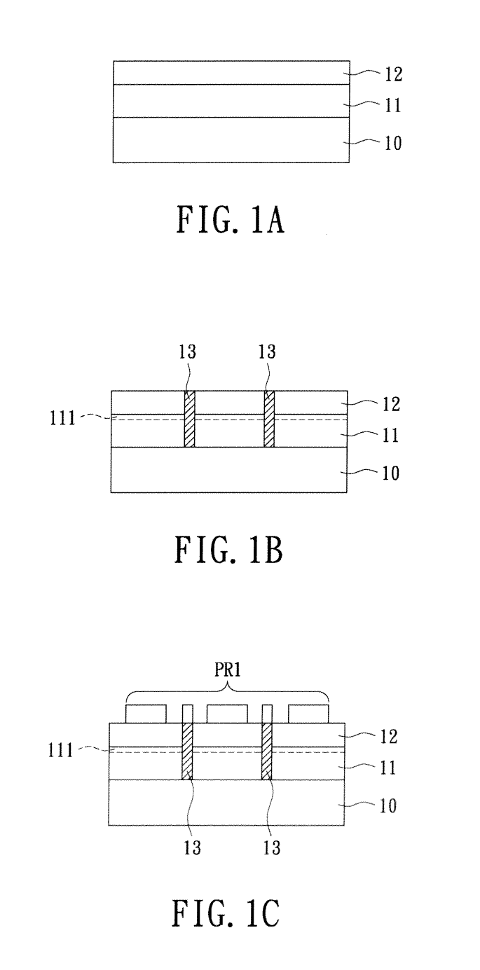

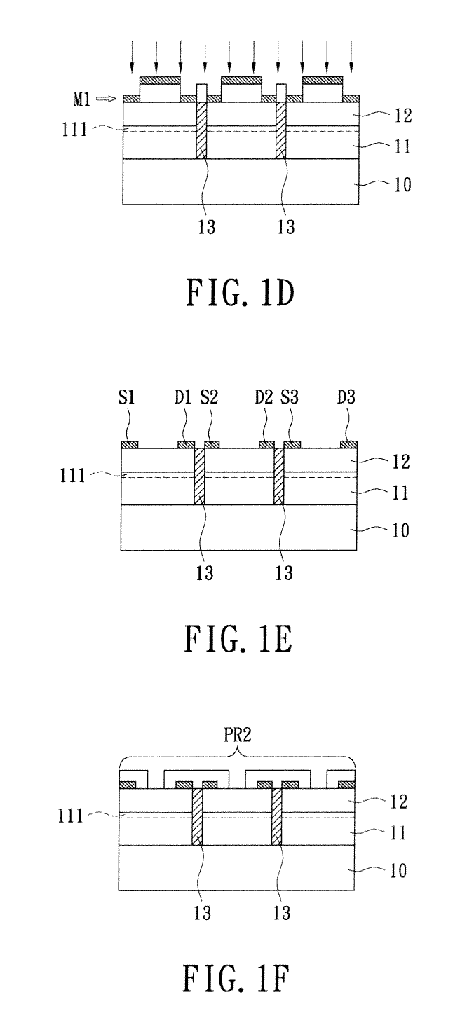

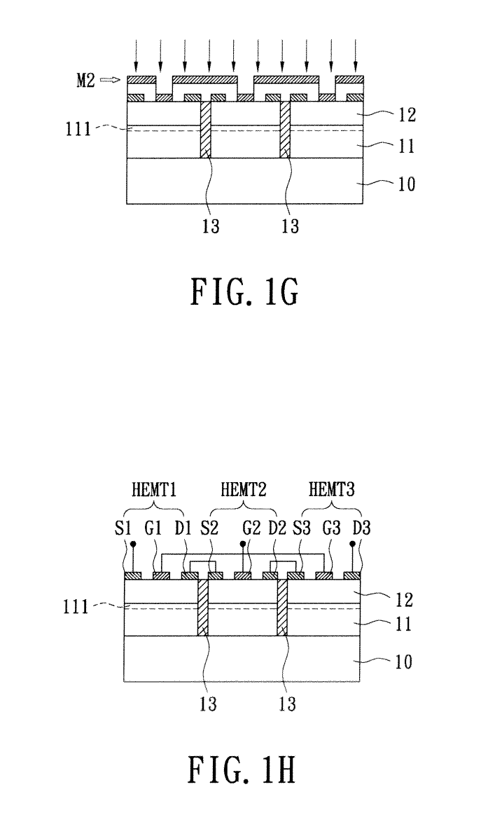

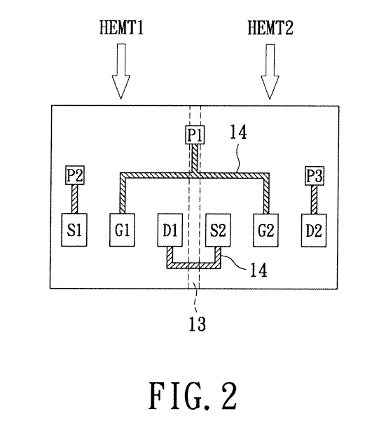

As shown in FIG. 1A to 1H and FIG. 2; the manufacturing method of the exemplary embodiment of the instant disclosure has following steps.

The first step is providing a substrate 10, as shown in FIG. 1A. The substrate 10 performs as a carrier of the series-connected high electron mobility transistors which is suitable for forming, growing, depositing materials of Group III-nitride thereon, for example, the substrate 10 may be a GaN (gallium nitride) substrate, a SiC (silicon carbide) substrate, an AlN (aluminum nitride) substrate, an AlGaN (Aluminium gallium nitride) substrate, a diamond substrate, a sapphire substrate, or a Si (silicon) substrate, but not restricted thereby.

Next step is forming a buffer layer 11 on the substrate 10, and forming a barrier layer 12 on the buffer layer 11. The buffer layer 11 can have high electrical resistance and may be a doped or un-doped Group III-nitride. In the exemplary embodiment, the buffer layer 11 is a GaN (gallium nitride) layer made by any suitable forming method or technology, for example, the GaN layer can be formed by vapor method in which the reaction gases such as ammonia (NH3) and trimethyl gallium are induced into a reactor so that the epitaxial film is formed on the substrate 10 in the reaction of the reaction gases. In detail, the nitrogen molecular element of the ammonia and the gallium element are reacting to form the GaN film on the substrate 10. The deposition method can be operated in desired temperature, for example, ranged from about 500 to 1200° C., preferably ranged from about 700 to 1100° C., and further preferably ranged from about 900 to 1000° C. On the other hand, the pressure determined in the reactor can be ranged from about 20 to 950 milli-bar.

Similar with the buffer layer 11, the barrier layer 12 can be a doped or un-doped Group III-nitride. In the exemplary embodiment, the barrier layer 12 can be a single layer of AlN, or AlGaN. Alternatively, the barrier layer 12 can be a multilayer of AlN and AlGaN. One characteristic of the barrier layer 12 is that the bandgap of the barrier layer 12 is wider than the buffer layer 11. The barrier layer 12 has a desired concentration of Al so that the interface (e.g., a hetero-interface, or a heterojunction) between the barrier layer 12 and the buffer layer 11 can have carrier of high concentration. In other words, the hetero-interface of the buffer layer 11 and the barrier layer 12 results in the formation of a carrier-rich conductive region usually referred to as a two dimensional electron gas or 2DEG and the 2DEG can define an active area 111. For example, the active area 111 is located in the buffer layer 11 and near the hetero-interface about tens of nanometers.

Next step is forming at least one isolation structure 13 to form at least two high electron mobility transistors (HEMTs) on the substrate 10. Please refer to FIG. 1B; two isolation structures 13 are formed to separate the buffer layer 11, the barrier layer 12 and the active area 111 to define three HEMTs. The isolation structures 13 are used to physically and insulatedly separate the single buffer layer 11, the single barrier layer 12 and the single active area 111 into separated parts of the HEMTs. The separated HEMTs are series-connected to form the device with high breakdown voltage of the present invention. Specifically, the isolation structures 13 are insulated material which penetrates in the single buffer layer 11, the single barrier layer 12 and the single active area 111. In other words, one of the isolation structures 13 is formed between the adjacent and separated HEMTs. The isolation structures 13 can be formed by semiconductor processes such as lithography, etch and so on.

Next step is forming a source electrode and a drain electrode on the barrier layer 12 of each of the high electron mobility transistors. Please refer to FIGS. 1C to 1E; a photoresist layer PR1 is formed by lithography processes to define ohmic contact area (as shown in FIG. 1C), and a metal layer M1 (as shown in FIG. 1D) is then formed by a deposition method on the photoresist layer PR1. Then, the photoresist layer PR1 is removed or striped, to from the source electrode and the drain electrode. In the embodiment as shown in figure, the left HEMT has the source electrode S1 and the drain electrode D1, the middle HEMT has the source electrode S2 and the drain electrode D2, and the right HEMT has the source electrode S3 and the drain electrode D3. The source electrode S1 (S2, S3) and the drain electrode D1 (D2, D3) are electrically connected to the active area 111 of the corresponding HEMT. In an exemplary embodiment, a connection of low-resist is formed by an annealing method so that the source electrode S1 (S2, S3) and the drain electrode D1 (D2, D3) are ohmically connected to the active area 111. On the other hand, the source electrode S1 (S2, S3) and the drain electrode D1 (D2, D3) can be Ti, Al, Au, Ni or the alloy thereof, but not restricted thereby.

Next step is forming a gate electrode on the barrier layer 12 of each of the high electron mobility transistors. The gate electrode is located between the source electrode and the drain electrode of the corresponding HEMT, and the gate electrode is electrically connected to the active area 111. As shown in FIG. 1F, a photoresist layer PR2 is formed by lithography processes to define gate area and then a metal layer M2 is deposited (as shown in FIG. 1G). Then, the photoresist layer PR2 is removed or striped, to from the gate electrode. In the embodiment as shown in figure, the left HEMT has a gate electrode G1 between the source electrode S1 and the drain electrode D1, the middle HEMT has a gate electrode G2 between the source electrode S2 and the drain electrode D2, and the right HEMT has a gate electrode G3 between the source electrode S3 and the drain electrode D3. The gate electrodes G1, G2, G3 can be Ni, Au, Ti, Cr, Pt, or the alloy thereof, and the gate electrodes G1, G2, G3 are electrically connected to the corresponding active area 111.

Please refer to FIG. 1H; the three isolated transistors HEMT1, HEMT2, HEMT3 are formed. Taking the HEMT1 as example, HEMT1 can be a normally ON device, and an appropriate voltage to the gate electrode G1 between the source electrode S1 and the drain electrode D1 causes the interruption of the 2DEG thereby turning the device OFF.

Next step is connecting the at least two high electron mobility transistors in a series manner to form the device of the present invention. As shown in FIG. 1H, the drain electrode D1 of HEMT1 is electrically connected to the source electrode S2 of HEMT2, and the drain electrode D2 of HEMT2 is electrically connected to the source electrode S3 of HEMT3. Moreover, the gate electrodes G1, G2, G3 of HEMT1. HEMT2, HEMT3 are connected to each other. Thus, HEMT1, HEMT2, HEMT3 are connected in series-connected manner. For the device formed by series-connecting HEMT1, HEMT2. HEMT3 can have high breakdown voltage resulted from the adding of breakdown voltage of each transistor. In other words, the source electrode of one of at least two high electron mobility transistors is connected electrically to the drain electrode of the other one of the at least two high electron mobility transistors, and the gate electrodes of the at least two high electron mobility transistors are connected with each other. As a result, the transistors are connected in series manner to form the high breakdown voltage device of the present invention.

In FIG. 2, the top view of the device of the present invention is shown. The series-connected structure between the two transistors, e.g., HEMT1 and HEMT2 are illustrated. The series-connected structure can be interconnections formed by semiconductor manufacturing processes, such as lithography, etch, metal deposition, and so on. For example, an interconnection 14 is formed between the gate electrodes G1, G2, and further connected to an external power via a conductive pad P1. On the other hand, drain electrode D1 is electrically connected to the source electrode S2 via the interconnection 14, and the source electrode S1 and drain electrode D2 are respectively connected to the pads P2, P3 to perform as an input end and an output end.

Therefore, the device of the present invention has at least two high electron mobility transistors (HEMTs) connected in a series manner (e.g., HEMT1, HEMT2, HEMT3). The at least two high electron mobility transistors is formed on a substrate 10 and separated by at least one isolation structure 13. Each high electron mobility transistor includes a buffer layer 11 formed on the substrate 10, a barrier layer 12 formed on the buffer layer 11. A 2DEG is formed substantially at the hetero-interface between the barrier layer 12 and the buffer layer 11 to define an active area 111. Each transistor further includes a source electrode (i.e., S1, S2 or S3), a drain electrode (i.e., D1, D2 or D3) and a gate electrode (i.e., G1, G2 or G3). The source electrode, the drain electrode and the gate electrode are formed on the barrier layer 12 and connected electrically to the corresponding active area 111. Further, the source electrode of one of at least two high electron mobility transistors is connected electrically to the drain electrode of the other one of the at least two high electron mobility transistors, and the gate electrodes of the at least two high electron mobility transistors are connected with each other. As a result, the transistors are connected in series manner during the manufacturing process to form the high breakdown voltage device of the present invention.

To sum up, the present invention provides some following advantages:

1. The manufacturing processes of the HEMTs are adjusted to series connect the HEMTs into an integral device. As a result, the equivalent circuit of the connected HEMTs can increase the breakdown voltage of the integral device.

2. The manufacturing process of the present invention is optimized and excludes complex steps. Further, the manufacturing cost of the present invention is low, and the manufacturing process can be applied for protecting the HEMTs from damage resulted from the manufacturing steps.

3. The high breakdown voltage device of the present invention can be used in cars, space application or high power applications. Moreover, the reliability of power circuit used in high temperature, high pressure can be improved.

What is claimed is:

1. A manufacturing method of a device having series-connected high electron mobility transistors, comprising following steps:
providing a substrate;
forming a buffer layer on the substrate;
forming a barrier layer on the buffer layer, wherein a two-dimensional electron gas (2DEG) is formed substantially at the hetero-interface between the barrier layer and the buffer layer to define an active area;
forming at least one isolation structure, separating the buffer layer, the barrier layer and the active area so as to form at least two high electron mobility transistors (HEMTs) on the substrate;
forming a source electrode and a drain electrode on the barrier layer of each of the high electron mobility transistors, wherein the source electrode and the drain electrode are electrically connected to the active area;
forming a gate electrode on the barrier layer of each of the high electron mobility transistors, wherein the gate electrode is located between the source electrode and the drain electrode, and the gate electrode is electrically connected to the active area;
connecting the at least two high electron mobility transistors in a series manner, wherein the source electrode of one of the at least two high electron mobility transistors is connected electrically to the drain electrode of the other one of the at least two high electron mobility transistors, and the gate electrodes of the at least two high electron mobility transistors are connected with each other.

2. The manufacturing method according to claim 1, wherein the isolation structure is formed and inserted through the buffer layer, the barrier layer and the active area in the step of forming at least one isolation structure.

3. The manufacturing method according to claim 1, wherein the source electrode and the drain electrode are electrically connected to the active area in an ohmic-contact manner in the step of forming a source electrode and a drain electrode.

4. The manufacturing method according to claim 1, wherein the at least two high electron mobility transistors are connected in a series manner via interconnections made by semiconductor manufacturing processes in the step of connecting the at least two high electron mobility transistors in a series manner.

5. A device having series-connected high electron mobility transistors, comprising: at least two high electron mobility transistors (HEMTs) connected in a series manner, the at least two high electron mobility transistors being formed on a substrate and separated by at least one isolation structure, each of the high electron mobility transistors including:
a buffer layer formed on the substrate;
a barrier layer formed on the buffer layer, wherein a two-dimensional electron gas (2DEG) is formed substantially at the hetero-interface between the barrier layer and the buffer layer to define an active area;
a source electrode, a drain electrode and a gate electrode, the source electrode, the drain electrode and the gate electrode being formed on the barrier layer and connected electrically to the active area, wherein the source electrode of one of the at least two high electron mobility transistors is connected electrically to the drain electrode of the other one of the at least two high electron mobility transistors, and the gate electrodes of the at least two high electron mobility transistors are connected with each other.

6. The device according to claim 5, wherein the isolation structure is formed between the at least two high electron mobility transistors to separate the buffer layers, the barrier layers and the active areas of the at least two high electron mobility transistors.

7. The device according to claim 5, wherein the source electrode and the drain electrode of each of the at least two high electron mobility transistors are electrically connected to the active area of the corresponding high electron mobility transistor in an ohmic-contact manner.

8. The device according to claim 5, wherein the substrate is a GaN substrate, a SiC substrate, an AlN substrate, an AlGaN substrate, a diamond substrate, a sapphire substrate, or a Si substrate.

9. The device according to claim 5, wherein the buffer layer is a doped or un-doped Group III-nitride layer.

10. The device according to claim 5, wherein the barrier layer is a single layer of doped or un-doped Group III-nitride, or a multilayer of doped or un-doped Group III-nitride.
